(19) United States
(12) Patent Application Publication
(10) Pub. No.: US 2007/0209202 A1
(43) Pub. Date: Sep. 13, 2007

(54) Method For the Production of Circuit Boards and/or Corresponding Constructs

(75) Inventor: Georg Busch, Ahaus (DE)

Correspondence Address: BELL, BOYD & LLOYD, LLP, P.O. BOX 1135, CHICAGO, IL, 60690, US

(73) Assignee: Siemens Aktiengesellschaft, Muenchen (DE)

(21) Appl. No.: 10/599,901

(22) PCT Filed: Mar. 2, 2005
(86) PCT No.: PCT/EP05/50919

§ 371 Date: Apr. 19, 2007

(30) Foreign Application Priority Data
Apr. 29, 2004 (DE) 102004021062.4

(51) Int. Cl. H05K 3/02; H01B 13/00

(52) U.S. Cl. 29/847; 29/852; 216/13; 174/250

(57) ABSTRACT

A method for producing printed circuit boards and/or corresponding constructs that includes points where through-connections are created. The method vitiates the need for a very complex brushing process by using low cost lacquer variants. Moreover, the disclosed methods allow additional strip conductors or appropriate layers to be guided directly across the through connections rather than just to the through connections.

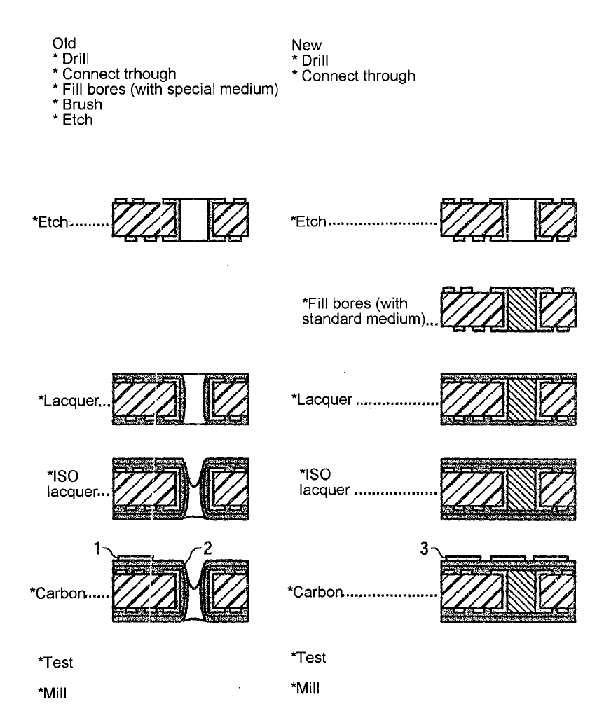

### FIELD OF TECHNOLOGY

The present disclosure relates to a method for the production of circuit boards and/or corresponding constructs

### BACKGROUND

In the production of circuit boards and/or corresponding constructs comprising points at which through-connections are created, the problem exists that a layer of insulating lacquer applied to the strip conductor image does not guarantee secure insulation, especially on the edges of the openings of the through-bores of the through-connections.

The reason for this is firstly that the insulating lacquer runs into the through-bores and peels off on the edges of the openings of the through-bores. As a result of this, the thickness of the layer of insulating lacquer becomes at least very thin on the edges concerned. Secondly, the layer of insulating lacquer is not 100% non-porous, so there are small, and very small, holes which cause the electrical resistance relative to the electrically conductive layer arranged thereunder, which in this case forms the electric through-connection, to become less than infinite.

This has a detrimental impact, for example, when a further electrically conductive layer, whether in the form of a further strip conductor, for example, or in the form of a larger area, for example, is arranged above the through-connection. The advantage that is achieved here is that the surface of the circuit board or of a corresponding construct is used substantially more intensively. That is, even those areas are used which are otherwise left free so as to prevent short-circuits to the through-connections.

The short-circuits here are not necessarily extremely low-impedance short-circuits in each case. Short-circuits are also present when the insulating resistance is less than infinite, so there is the possibility that creeping currents will flow.

A method for the production of circuit boards is known from document WO 02/078411 A, which is incorporated by reference in its entirety herein, said circuit boards having points at which through-connections are created, at least in the proximity of which strips connectors or an electrically conductive layer is also provided. Here the through-bores of the through-connections have diameters which are above a size range of 20 micrometers. Additionally a method step is lacking in which one through-connecting takes place in that an electrically conductive general layer is formed before the through-holes are filled with a standard medium.

A method for the production of multilayer circuit boards is known from U.S. Pat. No. 5,758,413 which is incorporated by reference in its entirely herein, with a diameter of 120 micrometers and less only for the through-connections.

### SUMMARY

Under exemplary embodiments, a simple and low-cost method is disclosed for the production of circuit boards and/or corresponding constructs comprising points at which through-connections are created and, at least in the proximity of said points, strip conductors or similar are also provided.

One advantage of the disclosed embodiment is that it is easy to control and limit short circuits that may be produced between the through-connections and the strip conductors or correspondingly similar arranged at least in the proximity of the through-connections.

The exemplary method is easy to control and is low in cost because very complex brushing (in which the surface of the circuit board or of a corresponding construct is brushed), is cut out. The method is also simple and low in cost because standard media can be used throughout and consequently it is not necessary to use special media at least in some method steps. The method also guarantees short-circuit protection above the through-connections in particular because in practice three insulation layers are applied above the through-connections. Thus, firstly, a relatively thick general insulation layer is created overall and secondly, with three insulation layers, the probability that open pores in each insulation layer will coincide precisely with one another three times is practically ruled out.

Also identical standard media can be used in several method steps in which previously special media were required at least in part.

A further advantage is that the standard media can be low-cost media.

A further advantage is that the strip conductors or such like arranged above the through-connections can be realized using low-cost carbon.

However, it is advantageous that the separation of individual circuit boards or corresponding constructs continues to be carried out by means of simple milling from a larger structure.

### BRIEF DESCRIPTION OF THE DRAWINGS

The various objects, advantages and novel features of the present disclosure will be more readily apprehended from the following Detailed Description when read in conjunction with the enclosed drawings, in which:

In the single drawing, the left-hand side illustrates the sequences of an existing method and is compared on the right-hand side with the sequences of an exemplary method according to the present disclosure for the production of circuit boards and/or corresponding constructs comprising points at which through-connections in the 20 μm size range are created, in the proximity of which points or above which points further strip conductors or corresponding are arranged.

### DETAILED DESCRIPTION

The existing method, based on the example of the production of a circuit board, comprises the following method steps:

1. Drilling of through-bores for the through-connections;

2. Production of through-connections;

3. Filling of bores of the through-connections with an etch-resistant plugging paste (=a special medium);

4. Brushing of the surfaces so that it is possible subsequently to produce the etched image (strip-conductor image) on plane and clean surfaces;

5. Etching of the circuit board, by which is meant all measures which are necessary for a finished strip conductor image to be produced;

6. Lacquering of the surfaces with a stop lacquer so that a first lacquer layer is applied which covers at least slightly the electrically conductive surfaces and surface elements (strip conductors) as well as the surfaces of the through-connections and also that the interspaces between the electrically conductive surface elements are at least partially filled;

7. Application of the actual insulating lacquer (ISO lacquer) so that overall firstly a plane surface is again provided and secondly a secure insulation exists in relation to the electrically conductive surfaces and surface elements arranged thereunder, which is why it is then possible that farther electrically conductive surfaces and surface elements can be provided on these surfaces, except above the through-connections, because ultimately as a result of the absence of a filling of the through-connections no plane surface is produced there. Here, the lacquer runs at least somewhat into the through-connection each time;

8. Application of further electrically conductive surfaces and surface elements (for example, carbon strip conductors (1)), whereby, for reasons of avoiding short circuits, a relatively large gap is maintained, especially on the edges (2) of the through-bores of the through connections on which only a particularly thin insulation forms;

9. Testing of the circuit board, and

10. Separation of the individual circuit board by milling of the circuit board from a group of circuit boards whereby, for reasons of efficiency, one circuit board is generally produced.

By comparison, am exemplary embodiment discloses a method comprising production of a circuit board, wherein the following steps are performed:

1. Drilling of through-bores for the through-connections;

2. Production of through-connections;

3. Etching of the circuit board, by which is meant all measures which are necessary for a finished strip conductor image to be produced;

4. Filling of the bores of the through-connections with a standard plugging paste (=standard medium in the form of a low-cost lacquer variant which achieves a saving effect and simplifies the method flow), it being possible at this point for complex and expensive brushing of the surfaces to be dispensed with (together with the omission of complex and expensive brushing of the surfaces prior to etching, as was otherwise required in the case of the previous process flow, this produces a further substantial saving effect and a further simplification of the method flow);

5. Lacquering of the surfaces with a stop lacquer so that a first lacquer layer is applied which covers at least slightly the electrically conductive surfaces and surface elements (strip conductors) and also fills the interspaces between the electrically conductive surface elements at least in part;

6. Application of the actual insulating lacquer (ISO lacquer) so that overall firstly a plane surface is again provided and secondly a secure insulation exists in relation to the electrically conductive surfaces and surface elements arranged thereunder, which is why it is then possible that further electrically conductive surfaces and surface elements can be provided on these surfaces, even directly above the through-connections;

7. Application of further electrically conductive surfaces and surface elements (for example, carbon strip conductors (3)), it now also being possible for these electrically conductive surfaces and surface elements to be guided at least to the through-connections and even directly across them;

8. Testing of the circuit board, and

9. Separation of the individual circuit board by milling of the circuit board from a group of circuit boards, whereby, for reasons of efficiency, one circuit board is generally produced.

The plugging paste, the stop lacquer and the insulating lacquer can all be identical under another exemplary embodiment, i.e. consist of just a single low-cost lacquer variant.

The application of the lacquer layers can be accomplished by means of the screen-printing method which is known in the art.

While the invention has been described with reference to one or more exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

1-5. (canceled)

6. A method for the production of circuit boards comprising the steps of:
drilling through-bores for establishing through-connections;
through-connecting, wherein an electrically conductive general layer is built up;
etching a strip conductor image into the electrically conductive general layer;
filling of the bores of the through-connections with a medium;
lacquering of the surfaces on which through-connections are present and, at least in the proximity of which, strip conductors are later provided;
applying an insulating lacquer to the surfaces of the circuit board; and
producing strip conductors arranged above the through-connections.

7. The method as claimed in claim 6, wherein the medium used in filling the bores and insulating lacquer is identical.

8. The method as claimed in claim 6, wherein the medium used in filling the bores and the insulating lacquer is a low cost lacquer variant.

9. The method as claimed in claim 6 wherein the strip conductors arranged above the through-connections are carbon.

10. The method as claimed in claim 6, further comprising separating individual circuit boards by means of a milling process.

11. The method as claimed in claim 6, wherein the through-bores are 20 μm in size.

12. The method as claimed in claim 6, wherein the insulating lacquer is an 150 lacquer.
